(19) United States
(12) Patent Application Publication
(10) Pub. No.: US 2012/0217619 A1
(43) Pub. Date: Aug. 30, 2012

(54) SEMICONDUCTOR DEVICE WITH TRIANGLE PRISM PILLAR AND METHOD FOR MANUFACTURING THE SAME

(76) Inventors: Min-Soo Kim, Gyeonggi-do (KR); Yong-Seok Eun, Gyeonggi-do (KR); Kee-Jeung Lee, Gyeonggi-do (KR); Eun-Shil Park, Gyeonggi-do (KR); Tae-Yoon Kim, Gyeonggi-do (KR)

(21) Appl. No.: 13/338,365

(22) Filed: Dec. 28, 2011

(30) Foreign Application Priority Data
Feb. 28, 2011 (KR) 10-2011-0017656

(51) Int. Cl. H01L 29/02; H01L 21/28

(52) U.S. Cl. 257/618; 438/597; 257/E29.002; 257/E21.158

(57) ABSTRACT

A semiconductor device includes a triangle prism pillar having a first, a second, and a third sidewall surface, a bit line contacted with the first sidewall surface of the pillar, and a word line adjacent to the second sidewall surface of the pillar over the bit line.

### CROSS-REFERENCE TO RELATED APPLICATIONS

The present application claims priority of Korean Patent Application No. 10-2011-0017656, filed on Feb. 28, 2011, which is incorporated herein by reference in its entirety.

### BACKGROUND

1. Field

Exemplary embodiments of the present invention relate to semiconductor fabrication technology, and more particularly, to a semiconductor device with a triangle prism pillar and a method for fabricating the same.

2. Description of the Related Art

With the increase in integration degree of DRAM (Dynamic Random Access Memory), further integration of a two dimensional (2D) structure may be difficult. To overcome such difficulties, a three-dimensional (3D) DRAM having a vertical gate (VG) (hereafter, referred to as VG DRAM) may be implemented as a DRAM device.

A cell of the VG DRAM includes a pillar formed over a substrate, a bit line (BL), and a vertical gate. The vertical gate is formed on sidewalls of the pillar, and the pillar includes a source and a drain formed in the pillar. A vertical channel is formed between the source and the drain by the vertical gate. The vertical gate becomes a word line.

In the cell having a vertical gate structure, the pillars are arranged in a matrix shape, and the bit lines and the word lines are formed to surround the pillars, when seen from the layout of the cell. However, when the width of the bit line is not sufficiently larger than the cross-section of the pillar, the bit line contacted with the side surface of the pillar is significantly slimmed, and the resistance of the bit line increases. In particular, when a bit line using a metal layer formed in a bi-layer type including titanium nitride and tungsten is applied, the entire resistance of the bit line may be further increased according to the contact resistance between titanium nitride and tungsten. To reduce the resistance of the bit line, the cell may be designed in such a manner that the bit line passes between the pillars. In this example, a process of contacting the bit line with a one-side pillar should be implemented. More specifically, a one-side-contact (OSC) process may be used. Hereafter, the OSC process is referred to as “sidewall contact process.” The sidewall contact process forms a bit line contact in one pillar of adjacent pillars, while insulating the other pillar.

FIG. 1 illustrates a conventional semiconductor device.

Referring to FIG. 1, a bit line 12 and a word line 13 are formed along sidewalls of a pillar 11. More specifically, one word line 13 and one bit line 12 are allocated to one pillar 11.

In the conventional semiconductor device, however, since one pillar is allocated to an area of 2D×2D (4F²), an area occupied by the pillar increases, and thus an area where the bit line and the word line are to be formed decreases. Therefore, sheet resistance increases.

### SUMMARY

An embodiment of the present invention is directed to a semiconductor device including a space where a bit line and a word line are to be formed may be sufficiently secured by reducing an area occupied by pillars in a cell having a vertical gate structure, and a method for fabricating the same.

In accordance with an embodiment of the present invention, a semiconductor device includes: a triangle prism pillar having a first, a second, and a third sidewall surface; a bit line contacted with the first sidewall surface of the pillar; and a word line adjacent to the second sidewall surface of the pillar over the bit line.

In accordance with another embodiment of the present invention, a semiconductor device includes: first and second triangle prism pillars facing each other with an insulation layer interposed between the first and second triangle prism pillars, wherein the first and second triangle prism pillars have a first, a second, and a third sidewall surface; a bit line contacted with the first sidewall surface of the first triangle prism pillar; and a word line formed over the bit line and adjacent to the second sidewall surface of the second triangle prism pillar.

In accordance with yet another embodiment of the present invention, a method for fabricating a semiconductor device includes: forming a primary line by etching a substrate; forming a plurality of secondary lines by dividing and etching the primary line; forming first and second triangle prism pillars that face each other and have three sidewall surfaces by etching the plurality of secondary lines; forming a bit line to be contacted with a first sidewall surface of the first triangle prism pillar; and forming a word line over the bit line such that the word line is adjacent to a second sidewall surface of the second triangle prism pillar.

### BRIEF DESCRIPTION OF THE DRAWINGS

FIG. 1 is a plan view of a conventional semiconductor device.

FIG. 2 is a plan view of a semiconductor device in accordance with an embodiment of the present invention.

FIGS. 3A to 3H illustrate a method for fabricating a semiconductor device in accordance with the embodiment of the present invention.

FIGS. 4A to 4D are plan views illustrating a pillar formation method.

FIG. 5A is a plan view of a pillar arrangement.

FIG. 5B is a perspective view of the pillar arrangement.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

The exemplary embodiments of the present invention provide an arrangement where two pillars are shared by one bit line in a cell having a vertical gate structure. Furthermore, the embodiments of the present invention provide a structure including a pillar that is divided into two parts. Therefore, the area of the pillar is reduced, and the area of a path through which a bit line and a word line are formed is increased. By reducing the area of the pillar, the sheet resistance of the word line and the bit line is reduced.

In the embodiments of the present invention, while bit line and word line allocation of 4F² is configured in 1 bit line-2 Tr, the horizontal and vertical arrangements of pillars are set in an oblique direction to enable addressing of a word line. In particular, the addressing of the word line may be performed without changing the form of 4F².

FIG. 2 is a plan view of a semiconductor device in accordance with an embodiment of the present invention.

Referring to FIG. 2, triangle prism pillars 103 and 104 having three sidewall surfaces are formed. A bit line 201 is formed to contact a first sidewall surface of the pillar 103 or 104. A word line 202 is formed adjacent to a second sidewall surface of the pillar 103 or 104 over the bit line 201, and the word line 202 crosses the bit line 201 over the bit line 201. The word line 202 has a vertical structure on the sidewall surface of the pillar 103 or 104. This structure is referred to as a vertical word line or vertical gate.

Specifically, the first and second triangle prism pillars 103 and 104 form one pair facing each other and each have three sidewall surfaces. The semiconductor device includes a plurality of first and second pillars 103 and 104. The plurality of first and second pillars 103 and 104 are arranged in a column direction and a row direction, respectively. A first sidewall of the bit line 201 is contacted with the first pillar 103, and a second sidewall of the bit line 201 is contacted with the second pillar 104. The word line 202 is formed adjacent to second sidewalls of the first and second pillars 103 and 104 over the bit line 201.

The first and second pillars 103 and 104 are formed by etching a substrate, and the first and second pillars 103 and 104 include silicon. The bit line 201 includes a metal. The bit line 201 may include titanium nitride and tungsten, and the bit line 201 may have a stacked structure of titanium nitride and tungsten. The word line 202 includes a metal. The word line 202 may include tungsten. A gate dielectric layer (not illustrated) is formed between the word line 202 and the pillars. A vertical channel is formed by the vertical word line 202.

When the word line 202 and the bit line 201 are formed in such a manner, one pillar is selected by the word line 201 even though the first and second pillars 103 and 104 are coupled to one bit line 201. For example, although a first pillar A1 and a second pillar A2 are contacted with a bit line B1, the second pillar A2 is selected by a word line W.

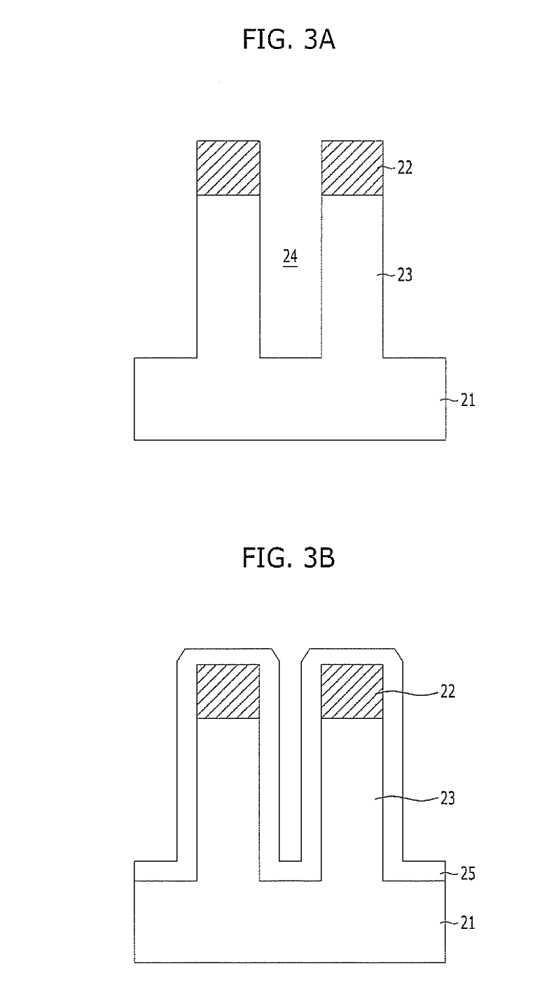

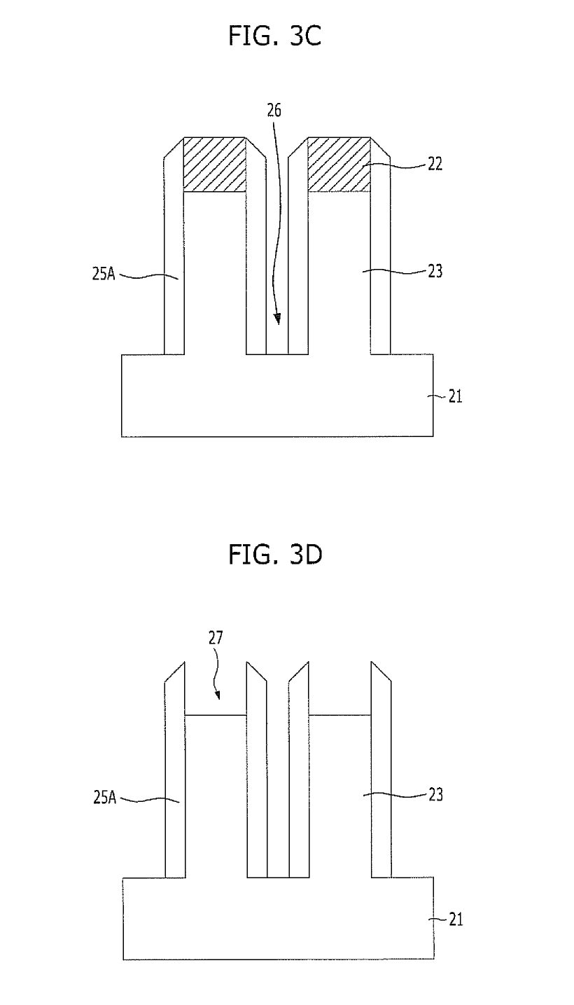

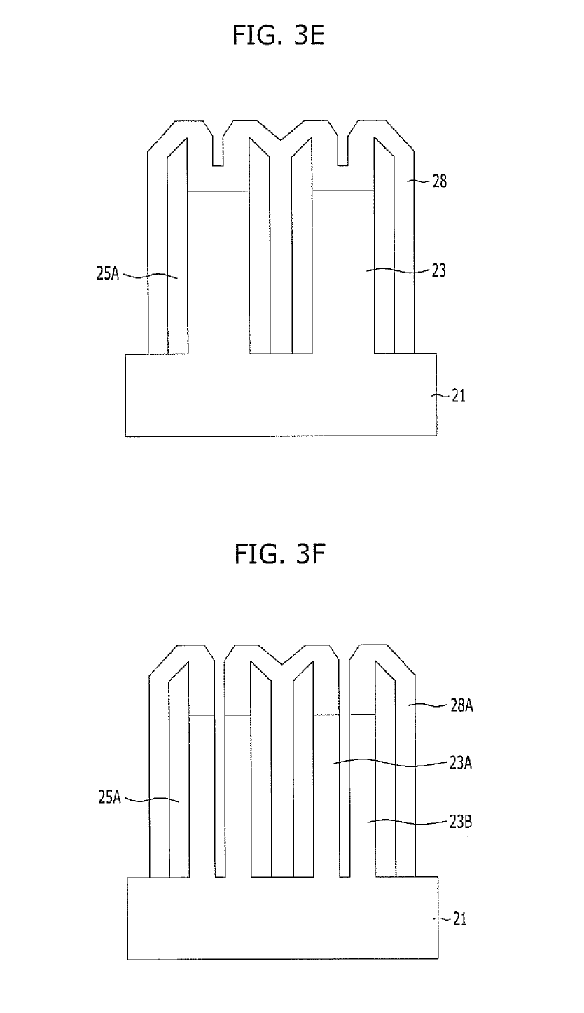

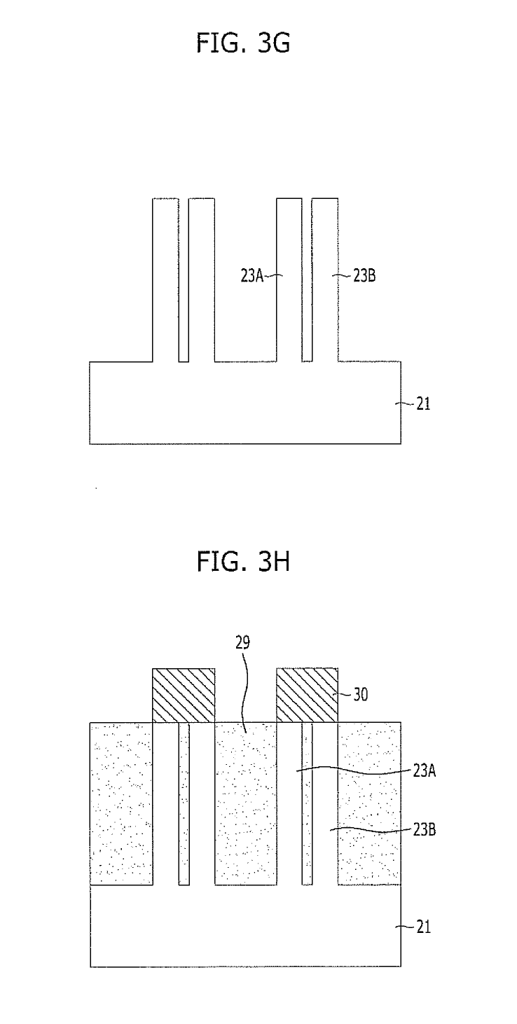

FIGS. 3A to 3H illustrate a method for fabricating a semiconductor device in accordance with the embodiment of the present invention.

Referring to FIG. 3A, a hard mask layer pattern 22 is formed over a substrate 21 such as a silicon substrate. The hard mask layer pattern 22 is formed by the following process. First, a hard mask layer is formed over the substrate 21 and then etched using a photoresist pattern (not illustrated) as an etch barrier. The hard mask layer pattern 22 may include a line and space pattern. The hard mask layer pattern 22 is formed of oxide or nitride. Furthermore, the hard mask layer pattern 22 may be formed by stacking oxide and nitride. In this embodiment of the present invention, nitride is used as the hard mask layer pattern 22. More specifically, the hard mask layer pattern 22 includes silicon nitride.

Using the hard mask layer pattern 22 as an etch barrier, the substrate 21 is etched to a designated depth to form a plurality of trenches 24. A plurality of primary lines 23 are formed over the substrate 21 by forming the plurality of trenches 24. The primary lines 23 are extended vertically from the surface of the substrate 21. The primary line 23 is where a channel region, a source region, and a drain region of a transistor are to be formed.

After the trench etching process, the plurality of primary lines 23 extended in a line type in a first direction are formed over the substrate 21, and the hard mask pattern 22 remains over the primary lines 23. When the substrate includes a silicon substrate, the primary line 23 becomes a silicon line.

Referring to FIG. 3B, a first spacer layer 25 is deposited on the entire surface of the resultant structure including the primary lines 23 and the hard mask layer 22. The first spacer layer 25 includes oxide or nitride. In this embodiment of the present invention, nitride is used as the first spacer layer 25. More specifically, the first spacer layer 25 may include silicon nitride.

Referring to FIG. 3C, primary spacer etching is performed to form a first spacer 25A on sidewalls of the primary lines 23. The primary spacer etching may include an etch-back process. The first spacer 25A is formed, for example, only on the sidewalls of the primary lines 23, and the substrate surface 26 between the primary lines 23 and the upper surface of the hard mask layer pattern 22 are exposed by the primary spacer etching.

Referring to FIG. 3D, the hard mask layer pattern 22 is removed to expose an upper surface 27 of the primary line 23. Accordingly, the upper portion of the first spacer 25A extends above the upper surface 27 of the primary line 23.

Referring to FIG. 3E, a second spacer layer 28 is formed on the first spacer 25A and the upper surface 27 of the primary line 23. The second spacer layer 28 includes oxide or nitride. In this embodiment of the present invention, nitride is used as the second spacer layer 28. More specifically, the second spacer layer 28 may include silicon nitride.

Referring to FIG. 3F, second spacer etching is performed to form a second spacer 28A. The second spacer etching may include an etch-back process. The second spacer 28A covers the extending upper portion of the first spacer 25A. The upper surface of the primary line 23 is exposed by the second spacer 28A.

The primary line 23 is etched using the second spacer 28A as an etch barrier. Accordingly, the primary line 23 is divided into a plurality of secondary lines 23A and 23B. The distance between the two secondary lines 23A and 23B is smaller than the distance between the primary lines 23. This distance between the two secondary lines is smaller than the distance between the primary lines 23 because the structure depends on the thickness of the second spacer 28A.

Referring to 3G, the first and second spacers 25A and 28A are removed. Therefore, the plurality of second lines 23A and 23B are formed over the substrate 21. The plurality of second lines 23A and 23B are arranged at a designated distance from each other and extend in a line type in the first direction.

Referring to FIG. 3H, an insulation layer 29 is formed to gap-fill the space between the secondary lines 23A and 23B, and the insulation layer 29 is subsequently planarized. Here, the insulation layer 29 includes oxide, and the planarization may include a chemical mechanical polishing (CMP) process.

A first mask 30 for etching the second lines 23A and 23B is formed. The first mask 30 has a line type extending in an oblique direction.

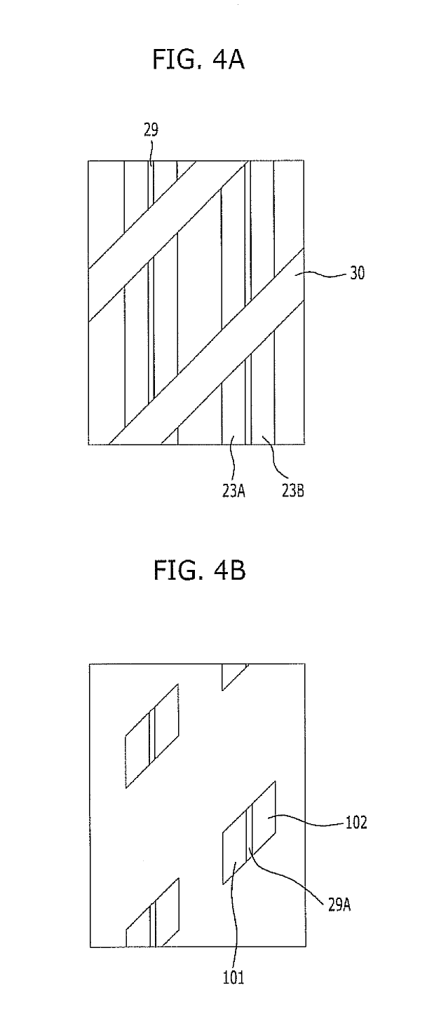

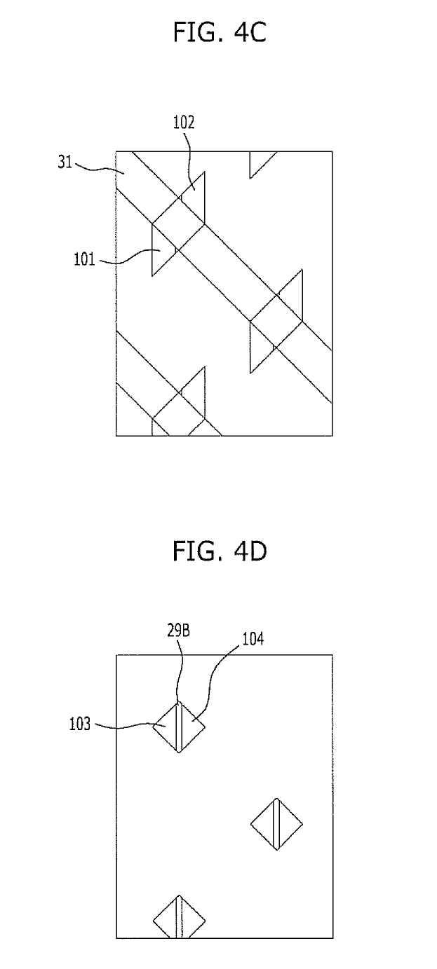

FIGS. 4A to 4D are plan views illustrating a pillar formation method.

FIG. 4A is a plan view of the first mask. Referring to FIG. 4A, the first mask 30 is formed with a line shape extending in a direction inclined at an angle of 45°, with respect to the primary lines 23A and 23B when seen from the top. However, the direction is not limited to 45°.

Hereafter, the following descriptions are based on plan views, for illustration purposes.

Referring to FIG. 4B, the plurality of primary lines 23A and 23B are etched using the first mask 30 as an etch barrier. Accordingly, preliminary pillars 101 and 102 are formed. As a result of the etching, the preliminary pillars 101 and 102 may have a trapezoid shape. Also, the insulation layer 29 is etched using the first mask 30 as an etch barrier. Accordingly, an insulation layer 29A is formed between the preliminary pillars 101 and 102.

Next, the first mask 30 is removed.

Referring to FIG. 4C, a second mask 31 is formed. The second mask 31 has a line shape extending in an oblique direction and covering a portion of the preliminary pillars 101 and 102. For example, the second mask 31 has a line shape extending in a direction crossing the first mask 30, when seen from the top.

The preliminary pillars 101 and 102 are etched using the second mask 31 as an etch barrier. Accordingly, pillars 103 and 104 are formed. The pillars 103 and 104 may become active regions. Also, the insulation layer 29A is etched using the second mask 31 as an etch barrier. Accordingly, an insulation layer 29B is formed.

Referring to FIG. 4D, the second mask 31 is removed.

After the second mask is removed, the pillars 103 and 104 form one pair of pillars, and plurality of pairs of pillars 103 and 104 are formed in a column direction and a row direction, respectively. When seen from above, the upper surfaces of the pillars 103 and 104 may have a triangle shape. Accordingly, two pillars 103 and 104 having a triangle prism shape form one pair of pillars facing each other. Hereafter, the pillars 103 and 104 forming one pair of pillars are referred to as the first and second pillars 103 and 104. The first and second pillars 103 and 104 have a triangle prism shape with three sidewall surfaces. Although will be described, a first sidewall surface of the three sidewall surfaces is contacted with a bit line, and a second sidewall surface is adjacent to a word line. The third sidewall surface faces the other pillar in the pair of pillars.

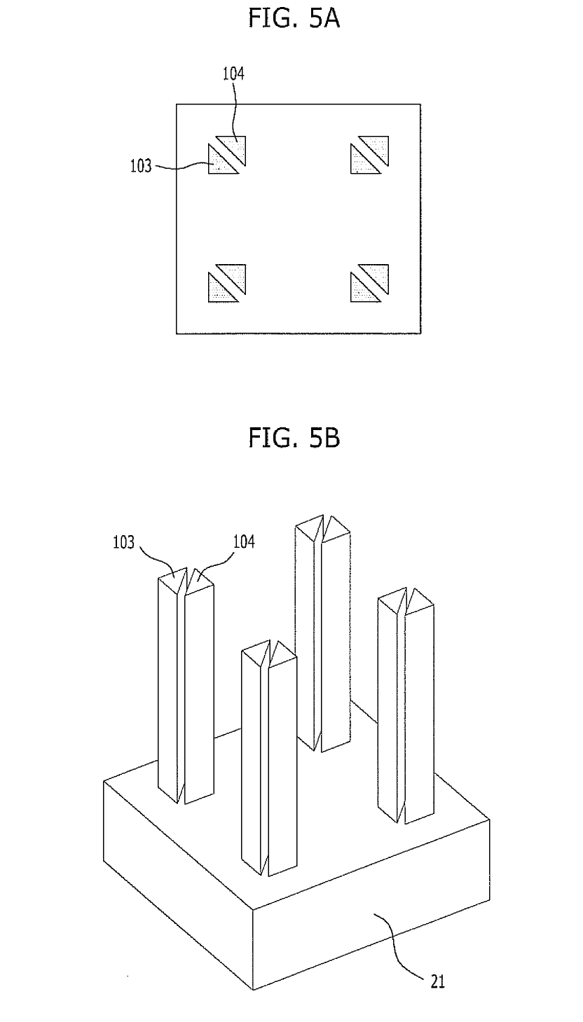

FIG. 5A is a plan view of the pillar arrangement. FIG. 5B is a perspective view of the pillar arrangement.

Returning to FIG. 2, a method for fabricating a bit line and a word line will be described.

First, a plurality of bit lines 201 are formed. The bit lines 201 are coupled to first sidewalls of the pillars 103 and 104 in a first direction and extended in a line type. The bit line 201 includes titanium nitride and tungsten. For example, the bit line 201 may be formed by stacking titanium nitride and tungsten. Furthermore, silicide may be formed for an ohmic contact between the bit line 201 and the first and second pillars 103 and 104.

Since the bit lines 201 contact the first sidewalls of the first and second pillars 103 and 104, this structure is referred to as a one side contact.

A plurality of word lines 202 are formed over the bit lines 201 in a direction crossing the bit lines 201. The word lines 202 are adjacent to second sidewalls of the pillars in a second direction and extended in a line type.

When the word lines 202 and the bit lines 201 are formed in such a manner, the first and second pillars 103 and 104 are contacted with the bit lines 201, and the word lines 202 are adjacent to the second sidewall of the first and second pillar 103 and 104. Therefore, although the plurality of first and second pillars 103 and 104 are coupled to the bit lines 201, any one first or second pillar 103 and 104 is selected by the word lines 202.

According to the above descriptions, the cell arrangement is formed at 4F² (2D×2D). In other words, one bit line 201 passes while contacting with the first and second pillars 103 and 104. At this time, although one bit line 201 selects two first pillars 103 formed in a triangle prism shape, only one first pillar 103 is selected by the word line 202 passing along one surface. In the embodiment of the present invention, the OSC method by the word line 202 is implemented.

Since the word line 202 passes along the upper portions of the pillars, the mask process and the etching process for an OSC may be easily performed. Therefore, the reduction of sheet resistance is maximized, and the OSC etching process may be performed at the level of the word lines 202.

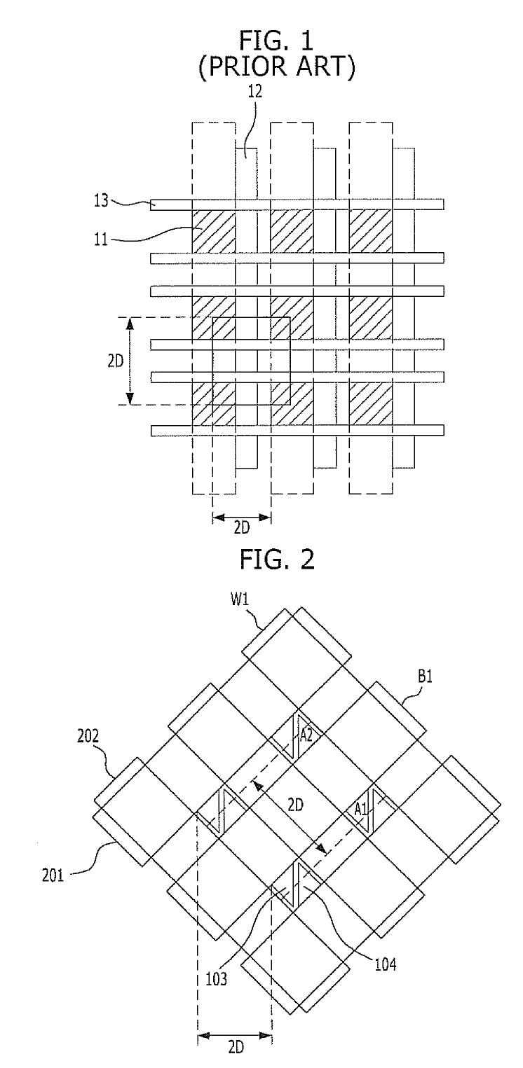

Furthermore, two kinds of pillar arrangements may be implemented at the same critical dimension (CD), and a CD loss does not occur. Referring to FIGS. 1 and 2, one pillar is allocated to an area of 2D×2D (4F² structure) in the conventional semiconductor device. In this embodiment of the present invention, however, since two pillars are allocated to an area of 1.414D×1.414D, the same integration degree may be acquired. Furthermore, when the distance between the primary lines 23 is reduced during the formation process of the primary lines 23, the formation space of the bit lines and the word lines may be sufficiently secured.

In accordance with the embodiments of the present invention, since the triangle prism pillars facing each other are used, the volume and area of the semiconductor device may be reduced. Furthermore, the entire area occupied by the pillars is reduced, and the space required for forming the bit line and the word line is increased, and sheet resistance may be reduced.

Furthermore, although one pillar is divided into two pillars, the pillars have a triangle shape, not a circle. Therefore, although a bit line passes while coming in contact with the pillars, the bit line has a large contact area.

While the present invention has been described with respect to the specific embodiments, it will be apparent to those skilled in the art that various changes and modifications may be made without departing from the spirit and scope of the invention as defined in the following claims.

What is claimed is:

1. A semiconductor device comprising:
a triangle prism pillar having a first, a second, and a third sidewall surface;
a bit line contacted with the first sidewall surface of the pillar; and
a word line adjacent to the second sidewall surface of the pillar over the bit line.

2. A semiconductor device comprising:
first and second triangle prism pillars facing each other with an insulation layer interposed between the first and second triangle prism pillars, wherein the first and second triangle prism pillars have a first, a second, and a third sidewall surface;
a bit line contacted with the first sidewall surface of the first triangle prism pillar; and
a word line formed over the bit line and adjacent to the second sidewall surface of the second triangle prism pillar.

3. The semiconductor device of claim 2, wherein the bit line and the word line cross each other perpendicularly.

4. The semiconductor device of claim 2, wherein the bit line comprises a metal.

5. The semiconductor device of claim 2, wherein a plurality of first and second triangle prism pillars are arranged in a column direction and a row direction, respectively, with a distance provided between the first and second triangle prism pillars.

6. The semiconductor device of claim 5, wherein the bit line is formed between the first and second triangle prism pillars arranged in the column direction, and the first triangle prism pillars are contacted with a first sidewall of the bit line and the second triangle prism pillars are contacted with a second sidewalls of the bit line.

7. The semiconductor device of claim 6, wherein the word line is adjacent to the second sidewall surface of the first triangle prism pillar.

8. The semiconductor device of claim 6, wherein the third sidewall surface of the first triangle prism pillar faces the third sidewall surface of the second triangle prism pillar.

9. A semiconductor device comprising:
first and second triangle prism pillars facing each other with an insulation layer interposed between the first and second triangle prism pillars, wherein the first and second triangle prism pillars have a first, a second, and a third sidewall surface;
a first vertical word line adjacent to the second sidewall surface of the first triangle prism pillar; and
a second vertical word line extended in parallel to the first vertical word line and adjacent to the second sidewall surface of the second pillar triangle prism.

10. The semiconductor device of claim 9, further comprising:
a first bit line formed under the first and second vertical word line and contacted with the first sidewall surface of the first triangle prism pillar; and
a second bit line formed under the first and second vertical word line, extended in parallel to the first bit line, and contacted with the first sidewall surface of the second triangle prism pillar,
wherein the first and second bit lines cross the first and second vertical word lines perpendicularly.

11. A method for fabricating a semiconductor device, comprising:
forming a primary line by etching a substrate;
forming a plurality of secondary lines by dividing and etching the primary line;
forming first and second triangle prism pillars that face each other and have three sidewall surfaces by etching the plurality of secondary lines;
forming a bit line to be contacted with a first sidewall surface of the first triangle prism pillar; and
forming a word line over the bit line such that the word line is adjacent to a second sidewall surface of the second triangle prism pillar.

12. The method of claim 11, wherein the forming of the first and second triangle prism pillars comprises:
forming a first mask in a line type over the secondary line;
forming a pair of preliminary pillars by etching the plurality of secondary lines using the first mask as an etch barrier;
forming a second mask in a line type crossing the first mask; and
etching the pair of preliminary pillars using the second mask as an etch barrier.

13. The method of claim 12, wherein the first and second masks cross each other perpendicularly.

14. The method of claim 12, wherein the first mask is formed in a direction which is inclined at 45° with respect to the plurality of secondary lines, and the second mask is formed in a direction which is inclined at −45° with respect to the plurality of secondary lines.

15. The method of claim 11, further comprising, after the forming of the secondary line:
forming an insulation layer to gap-fill a trench between the secondary lines; and
planarizing the insulation layer.

16. The method of claim 11, wherein the forming of the primary line by etching the substrate comprises:
forming a hard mask layer over the substrate;
etching the hard mask layer using a photoresist pattern;
etching the substrate for form a plurality of trenches and the primary line between the plurality of trenches.

17. The method of claim 16, wherein the forming a plurality of secondary lines comprises:
forming a first spacer layer over the substrate, the hard mask pattern and sidewalls of the primary line;
etching the first spacer formed on a surface of the substrate and an upper surface of the hard mask pattern;
removing the hard mask pattern;
forming a second spacer layer over an upper surface of the primary line and second spacer layer that is formed on the sidewalls of the primary line and extends above the upper surface of the primary line;
etching the second spacer to expose a portion of the upper surface of the primary line;
etching the primary line using the second spacer as an etch mask;
removing the first and second spacers;

18. The method of claim 11, further comprising:
forming a plurality of bit lines;
forming a plurality of word lines over the plurality of bit lines;
the first sidewall of the first and second triangle prism pillars contacts a bit line;
the second sidewall of the first and second triangle prism pillars is adjacent to a word line.
